(19) United States
(12) Patent Application Publication
(10) Pub. No.: US 2024/0332195 A1
(43) Pub. Date: Oct. 3, 2024

(54) SPRAY-COATED PHOTORESIST AND PHOTOIMAGEABLE DIELECTRICS TO ENABLE TSV BRIDGE FOR GLASS CORE PACKAGES

(71) Applicant: Intel Corporation, Santa Clara, CA (US)

(72) Inventors: Naiya SOETAN-DODD, Mesa, AZ (US); Srinivas V. PIETAMBARAM, Chandler, AZ (US); Suddhasattwa NAD, Chandler, AZ (US); Brandon C. MARIN, Gilbert, AZ (US); Sheng C. LI, Gilbert, AZ (US); Liwei CHENG, Chandler, AZ (US)

(21) Appl. No.: 18/129,879

(22) Filed: Apr. 2, 2023

(51) Int. Cl. H01L 23/538

(52) U.S. Cl. CPC H01L 23/5384; H01L 23/5381; H01L 23/5383; H01L 24/16; H01L 2224/16235

(57) ABSTRACT

Embodiments disclosed herein include an electronic package. In an embodiment, the electronic package comprises a core, where the core comprises glass. In an embodiment, a cavity is in the core, and a bridge is in the cavity. In an embodiment, the bridge comprises through substrate vias (TSVs). In an embodiment, pads are at a bottom of the cavity, where the TSVs are electrically coupled to the pads.

### TECHNICAL FIELD

Embodiments of the present disclosure relate to electronic systems, and more particularly to electronic packages with glass cores and embedded bridges that have through substrate vias (TSVs).

### BACKGROUND

In advanced electronics packaging applications, embedded bridges can be used in order to communicatively couple together two or more dies that are provided over the package substrate. The bridge is a substrate that can enable high density routing in order to provide enhanced communication bandwidth between the pair of dies. For example, the bridge is often fabricated from a silicon die. In a basic implementation, the bridge is entirely passive, and only includes electrical traces that are for coupling the two overlying dies together. In such instances power delivered to the two top dies needs to be routed around the bridge.

However, in some applications, power can be routed through the bridge. That is, the power delivery path may pass through a thickness of the bridge. This allows for more direct power delivery routes to the overlying dies. The power delivery path may include through substrate vias (TSVs) (also referred to as through silicon vias (TSVs) in the case of a silicon bridge). In the case of an organic package substrate, bridges with TSVs have been integrated in existing architectures.

As packaging architectures continue to advance to more complex systems, glass cores have been proposed. Unfortunately, glass core architectures provide additional processing limitations. This makes the integration of TSVs into the bridge more complex.

### BRIEF DESCRIPTION OF THE DRAWINGS

FIG. 1 is a cross-sectional illustration of an electronic package that includes a glass core with an embedded bridge that includes through substrate vias (TSVs), in accordance with an embodiment.

FIGS. 2A-2O are cross-sectional illustrations depicting a process for forming an electronic package with a glass core and an embedded bridge with TSVs, in accordance with an embodiment.

FIG. 3 is a cross-sectional illustration of an electronic package that includes a glass core with an embedded bridge that includes TSVs, in accordance with an additional embodiment.

FIGS. 4A-4J are cross-sectional illustrations depicting a process for forming an electronic package with a glass core and an embedded bridge with TSVs, in accordance with an additional embodiment.

FIG. 5 is a cross-sectional illustration of an electronic package with a glass core and an embedded bridge with TSVs, in accordance with an embodiment.

FIGS. 6A-6K are cross-sectional illustration depicting a process for forming an electronic package with an embedded bridge with TSVs, in accordance with an embodiment.

FIG. 7 is a cross-sectional illustration of an electronic system that includes a package substrate with a glass core and an embedded bridge that includes TSVs, in accordance with an embodiment.

FIG. 8 is a schematic of a computing device built in accordance with an embodiment.

### EMBODIMENTS OF THE PRESENT DISCLOSURE

Described herein are electronic packages with glass cores and embedded bridges that have through substrate vias (TSVs), in accordance with various embodiments. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

As noted above, advanced packaging architectures have been moving towards the inclusion of embedded bridge dies in order to communicatively couple together two or more overlying dies. The embedded bridge often includes silicon or another material capable of providing high density routing. High density routing enables high bandwidth communication between the overlying dies. However, power delivery is still needed to the overlying dies. As such, the power delivery needs to be provided around the embedded bridge. Alternatively, through substrate vias (TSVs) (also commonly referred to as through silicon vias in the case of a silicon substrate) can be provided through a thickness of the embedded bridge in order to directly route power to the overlying dies. Existing solutions include TSVs when the package substrate is substantially all organic. For example, an organic core (with or without glass reinforcement) has been used in conjunction with embedded bridges with TSVs.

However, existing integration approaches do not work in conjunction with glass core architectures. Glass cores require alternative patterning processes in order to form interconnects and vias. Additionally, pads need to be formed at the bottom of the cavity in which the bridge is embedded. Plating up pads in a cavity architecture is difficult.

Accordingly, embodiments disclosed herein include pattering and assembly processes that enables a glass core with a bridge that include TSVs. In some embodiments, the pads below the embedded bridge are formed with a spray-coated photoresist solution. The spray-coated resist can be applied locally to the bridge cavities and the remainder of the panel via X-Y positioning and tilting of the nozzle. In some embodiments, protection layers may also be used to protect surfaces from etching chemistries used to pattern the glass core.

While embodiments disclosed herein include the use of glass core architectures, it is to be appreciated that the bridge does not need to be embedded in the glass core. For example, bridges with TSVs may also be embedded within the buildup layers over the glass core. Such embodiments may also benefit from spray coating processes as well.

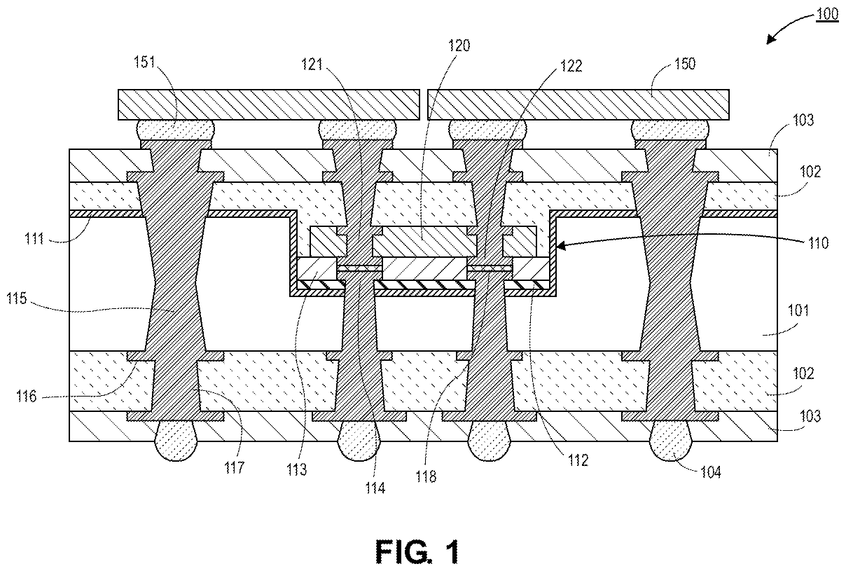

Referring now to FIG. 1, a cross-sectional illustration of an electronic package 100 is shown, in accordance with an embodiment. In an embodiment, the electronic package 100 may comprise a core 101. The core 101 may comprise glass. For example, the core 101 may comprise substantially all glass. That is, the core 101 is different than an organic core that may be reinforced with glass fibers. In an embodiment, the glass may include glass formulations that are compatible with laser assisted patterning processes. For example, the glass may include a borosilicate glass, a fused silica glass, or the like.

In an embodiment, buildup layers 102 may be provided over and under the core 101. The buildup layers 102 may comprise organic material, such as buildup film or the like. In an embodiment, pads 116, vias 117, and traces (not shown) may be provided through the buildup layers 102 in order to provide electrical routing. Through glass vias (TGVs) 115 may provide electrical routing through the core 101. Solder resist layers 103 may be provided over buildup layers 102. Interconnects 104 may provide coupling to a board (not shown), and interconnects 151 may provide coupling to dies 150.

In an embodiment, a cavity 110 is provided into a surface of the core 101. In the illustrated embodiment, the cavity 110 has substantially vertical sidewalls. Though, in other embodiments, the sidewalls of the cavity 110 may be tapered. The cavity 110 may be lined with a liner 111. The liner 111 may cover the sidewalls and portions of a bottom surface of the cavity 110. The liner 111 may also be provided over a top surface of the core 101. In an embodiment, a photoimageable dielectric (PID) 112 may be provided over the liner 111 at the bottom of the cavity 110. In an embodiment, pads 114 may be provided over the PID 112.

In an embodiment, a bridge 120 is positioned within the cavity 110. The bridge 120 may include a silicon substrate or any other substrate capable of supporting high density routing. The bridge 120 may be electrically coupled to the overlying dies 150 by conductive routing (e.g., vias 117, pads 116, etc.). The bridge 120 may communicatively couple together the two overlying dies 150. In an embodiment, the bridge 120 may further comprise TSVs 121. The TSVs 121 allow for power to pass through a thickness of the bridge 120. As such, power delivery does not need to be routed around the cavity 110. In an embodiment, a pad 122 at the bottom of the TSV 121 may be coupled to the bottom pads 114 by an interconnect 118, such as a solder or the like. In an embodiment, the interconnect 118 and the pads 114 and 122 may be surrounded by an underfill 113.

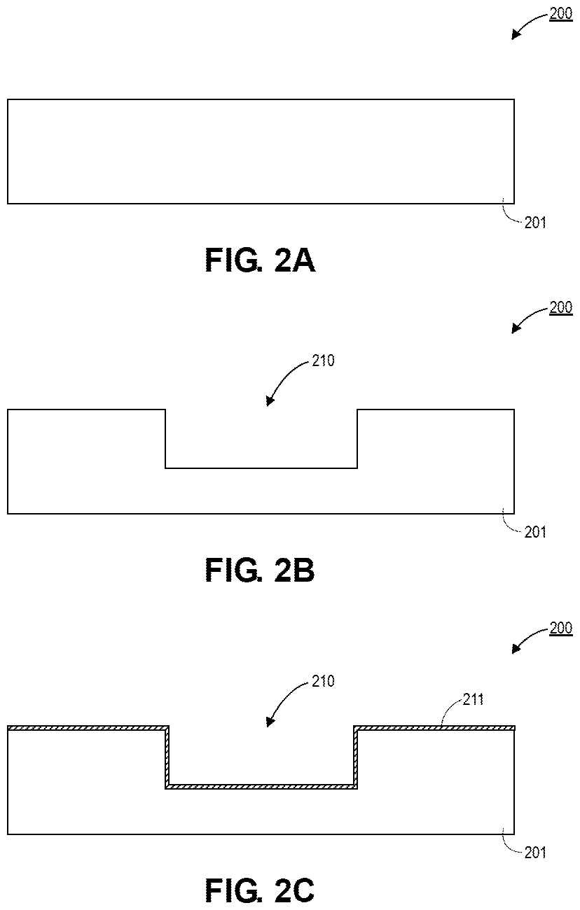

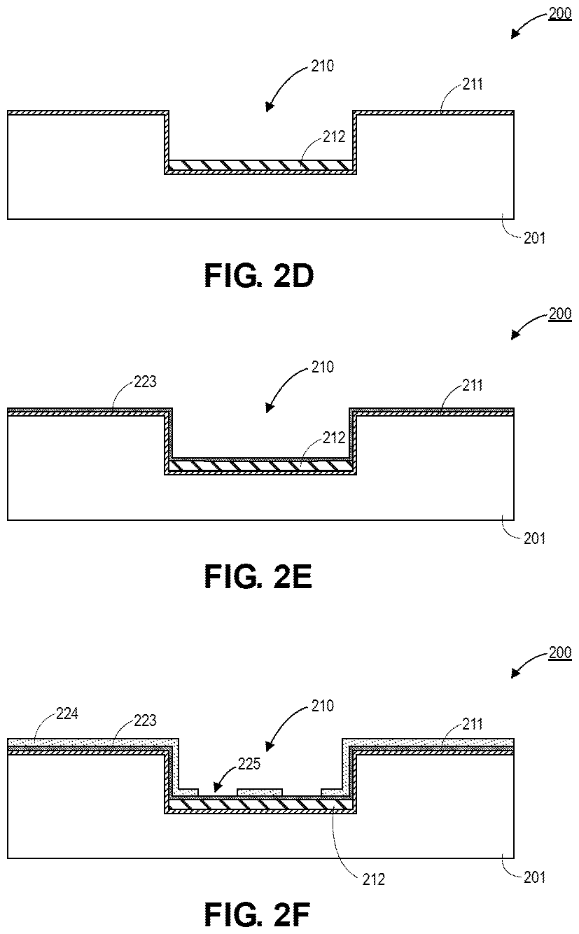

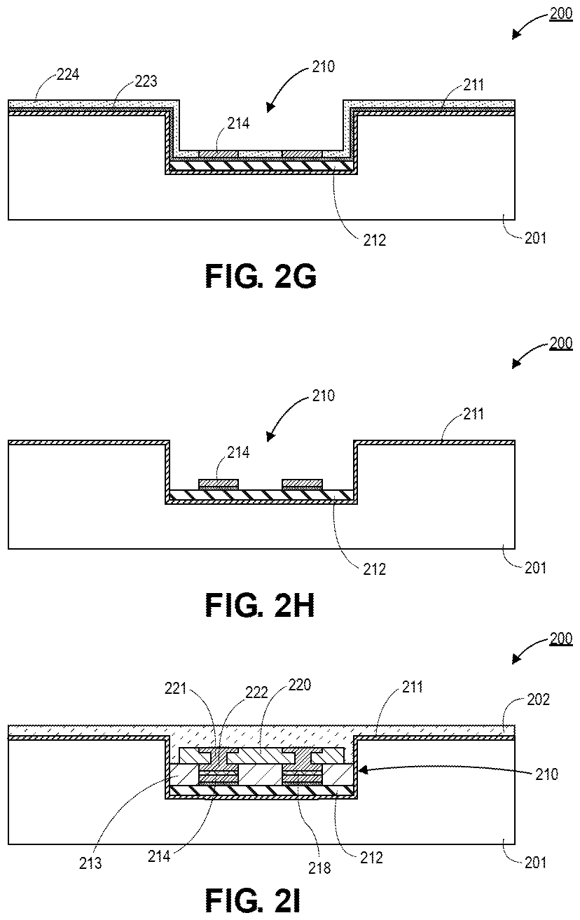

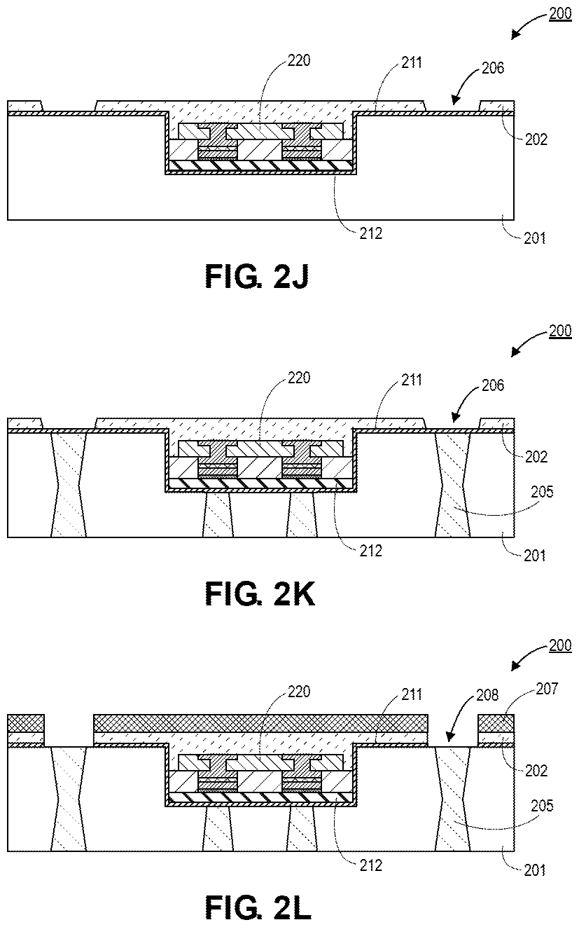

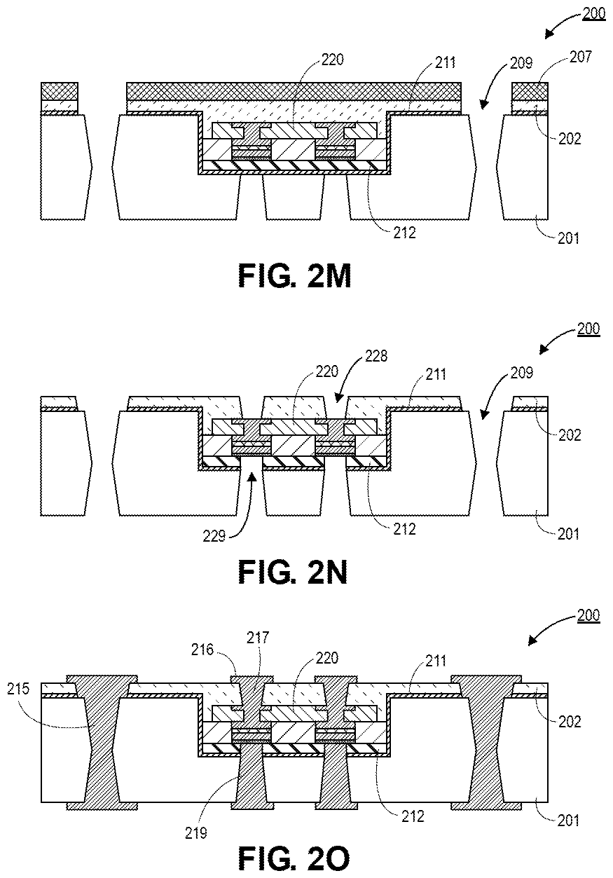

Referring now to FIGS. 2A-2O, a series of cross-sectional illustrations depicting a process for forming an electronic package 200 is shown, in accordance with an embodiment. The electronic package 200 shown in FIGS. 2A-2O may be similar to the electronic package 100 shown in FIG. 1.

Referring now to FIG. 2A, a cross-sectional illustration of the electronic package 200 at a stage of manufacture is shown. In FIG. 2A, a core 201 is illustrated. The core 201 may comprise glass. The glass formulation of the core 201 may be a glass that is compatible with laser assisted patterning processes. In such processes, a laser exposes the glass, and the exposed regions undergo a phase or microstructure transformation. The transformed regions are then preferentially etched with a wet etching process. In an embodiment, the core 201 may have any suitable thickness. For example, the thickness of the core 201 may be between approximately 50 μm and approximately 1,000 μm. Though, thicker or thinner cores 201 may be used in some embodiments. As used herein, “approximately” may refer to a range of values within ten percent of the stated value. For example, approximately 1,000 μm may refer to a range between 900 μm and 1,100 μm.

Referring now to FIG. 2B, a cross-sectional illustration of the electronic package 200 after a cavity 210 is formed is shown, in accordance with an embodiment. In an embodiment, the cavity 210 may be formed with a laser assisted etching process. The cavity 210 may have substantially vertical sidewalls. In other embodiments, the cavity 210 may have tapered sidewalls. For example, a width of the top of the cavity 210 may be wider than a width of the bottom of the cavity 210. In an embodiment, the cavity 210 may be provided to a depth that is approximately half the thickness of the core 201 or greater. Though, shallower cavities 210 may also be used in some embodiments.

Referring now to FIG. 2C, a cross-sectional illustration of the electronic package 200 after a liner 211 is formed is shown, in accordance with an embodiment. In an embodiment, the liner 211 conforms to the surface of the core 201. As such, the liner 211 is provided over a top surface of the core 201, along sidewalls of the cavity 210, and over the bottom surface of the cavity 210. In an embodiment, the liner 211 may be a material that is resistant to an etching chemistry used to etch the core 201 in a subsequent processing operation. For example, the liner 211 may comprise silicon and nitrogen (e.g., Si_{X}N_{Y}).

Referring now to FIG. 2D, a cross-sectional illustration of the electronic package 200 after a PID 212 is applied to the bottom of the cavity 210 is shown, in accordance with an embodiment. In an embodiment, the PID 212 may be applied with a spray coating process, a slit coating process, or the like. A PID 212 is used in order to allow for photolithography patterning operation in a subsequent processing operation.

Referring now to FIG. 2E, a cross-sectional illustration of the electronic package 200 after a seed layer 223 is applied is shown, in accordance with an embodiment. In an embodiment, the seed layer 223 may comprise titanium and copper. For example, a layer of titanium may be applied, followed by a layer of copper. The seed layer 223 may be applied with any suitable process. For example a sputtering process may be used in some embodiments. As such, the seed layer 223 can be applied over the top surface of the core 201, along sidewalls of the cavity 210, and over the bottom of the cavity 210.

Referring now to FIG. 2F, a cross-sectional illustration of the electronic package 200 after a resist layer 224 is applied and patterned is shown, in accordance with an embodiment. In an embodiment, the resist layer 224 may be applied with a spray coating process. As such, the resist can be applied over the top surface of the core 201, along sidewalls of the cavity 210, and over the bottom of the cavity 210. In an embodiment, the resist layer 224 is a photosensitive resist material. As such, regions may be exposed and developed in order to form openings 225. The openings 225 may be provided at the bottom of the cavity 210. The openings 225 may expose portions of the seed layer 223.

Referring now to FIG. 2G, a cross-sectional illustration of the electronic package 200 after pads 214 are formed is shown, in accordance with an embodiment. The pads 214 may be formed with a plating process, such as electrolytic plating. The pads 214 may be at the bottom of the cavity 210. The pads 214 may be configured to be coupled to a bridge provided in a subsequent processing operation.

Referring now to FIG. 2H, a cross-sectional illustration of the electronic package 200 after the resist layer 224 is stripped is shown, in accordance with an embodiment. In an embodiment, the resist layer 224 may be removed with a resist stripping process. After the resist layer 224 is removed, the exposed portions of the seed layer 223 may be removed with a flash etching process or the like. The resulting structure includes pads 214 (and underlying seed layer 223) that is provided over a top surface of the PID 212 at the bottom of the cavity 210.

Referring now to FIG. 2I, a cross-sectional illustration of the electronic package 200 after a bridge 220 is inserted into the cavity 210 is shown, in accordance with an embodiment. In an embodiment, the bridge 220 may comprise silicon or any other suitable bridge substrate. The bridge 220 may include TSVs 221 that are coupled to pads 222. In an embodiment, the pads 222 may be coupled to the pads 214 by interconnects 218. For example, the interconnects 218 may comprise solder or the like. The pads 214, interconnects 218, and pads 222 may be surrounded by an underfill 213. The underfill 213 may comprise capillary underfill (CUF) material or the like. After the bridge 220 is coupled to the core 201, a buildup layer 202 may be provided over the top surface of the core 201. The buildup layer 202 may fill the remainder of the cavity 210. The buildup layer 202 may be applied with a lamination process, or the like.

Referring now to FIG. 2J, a cross-sectional illustration of the electronic package 200 after openings 206 are formed into the buildup layer 202 is shown, in accordance with an embodiment. In an embodiment, the openings 206 may be provided outside of the footprint of the bridge 220. The openings 206 may expose portions of the liner 211.

Referring now to FIG. 2K, a cross-sectional illustration of the electronic package 200 after a laser exposure of the core 201 is shown, in accordance with an embodiment. The laser exposure may result in the formation of exposed regions 205. The exposed regions 205 may have a microstructure or phase that is different than the remainder of the core 201. In an embodiment, a dual sided exposure is done. The top surface can be exposed through the openings 206, and the bottom surface may be similarly exposed. The dual sided exposure may result in regions 205 that have hourglass shaped profiles. The bottom exposure may also be aligned over the pads at the bottom of the bridge 220.

Referring now to FIG. 2L, a cross-sectional illustration of the electronic package 200 after a resist layer 207 is applied over the buildup layer 202 and patterned to form openings 208 is shown, in accordance with an embodiment. In an embodiment, the resist layer 207 is a material that is resistant to the etching of core 201. Additionally, the exposed portions of the liner 211 may be removed, e.g., with a desmear process.

Referring now to FIG. 2M, a cross-sectional illustration of the electronic package 200 after the core is etched to form openings 209 is shown, in accordance with an embodiment. In an embodiment, the etching process may be a wet etching process. For example, an etching chemistry comprising hydrogen and fluorine (e.g., HF) may be used to remove the exposed regions 205. The openings 209 below the bridge 220 may land on the liner 211. As such, the pads below the bridge 220 are protected from the etching process.

Referring now to FIG. 2N, a cross-sectional illustration of the electronic package 200 after the pads are exposed with openings 229 is shown, in accordance with an embodiment. In an embodiment, the openings 229 may be formed with a dry desmear process or the like. Additionally, via openings 228 may be formed through the buildup layer 202 to provide access to the top of the bridge 220.

Referring now to FIG. 2O, a cross-sectional illustration of the electronic package 200 after vias are plated is shown, in accordance with an embodiment. In an embodiment, through core vias 215 may be adjacent to the bridge 220. Vias 217 and pads 216 may be coupled to the top side of the bridge 220. Similarly, vias 219 that pass through the core 201, the liner 211, and the PID 212 may provide electrical coupling to the bottom side of the bridge 220.

After the operations shown in FIG. 2O, standard processes may be implemented in order to form buildup layers above and below the core 201. For example, semi-additive processing (SAP) may be used to form one or more buildup layers in order to provide the necessary routing. The ultimate structure may be similar the electronic package 100 descried above with respect to FIG. 1.

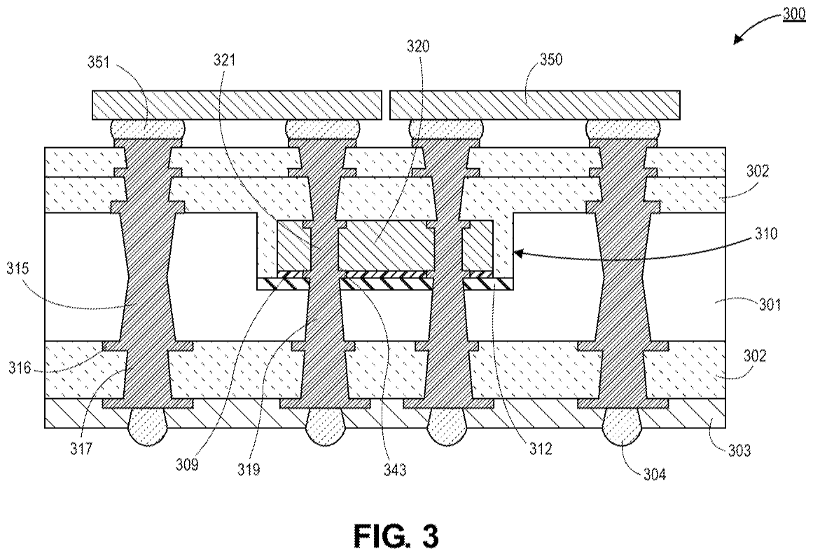

Referring now to FIG. 3, a cross-sectional illustration of an electronic package 300 is shown, in accordance with an additional embodiment. In an embodiment, the electronic package 300 may comprise a core 301. The core 301 may be a glass core. For example, the core 301 may be similar to the core 101 described in greater detail above. In an embodiment, buildup layers 302 may be provided over and under the core 301. Electrical routing (e.g., pads 316, vias 317, and traces (not shown)) may be provided through the buildup layers 302. In an embodiment, TGVs 315 may be provided through a thickness of the core 301. Additionally, vias 319 may provide electrical coupling to a bottom of the embedded bridge 320.

In an embodiment, the bridge 320 may be a silicon substrate or the like. The bridge 320 may include TSVs 321 to provide electrical coupling between a top and bottom surface of the bridge 320. In an embodiment, pads 343 may be provided at the bottom of the bridge 320. The pads 343 may be electrically coupled to the vias 319. The bridge 320 may be coupled to a PID 312 by a die attach film (DAF) 309 in some embodiments. The bridge 320 may communicatively couple together a pair of dies 350. The dies 350 may be coupled to the package substrate within interconnects 351, such as solder or the like. In particular embodiments, the TSVs 321 are configured to be power supply lines in order to provide power to the overlying dies 350. As such, power does not need to be routed around the cavity 310.

In an embodiment, a backside of the electronic package 300 may comprise a solder resist 303 or the like. Interconnects 304 may be provided through the solder resist 303. The interconnects 304 may be solder balls or the like. The interconnects 304 may be coupled to a board (not shown).

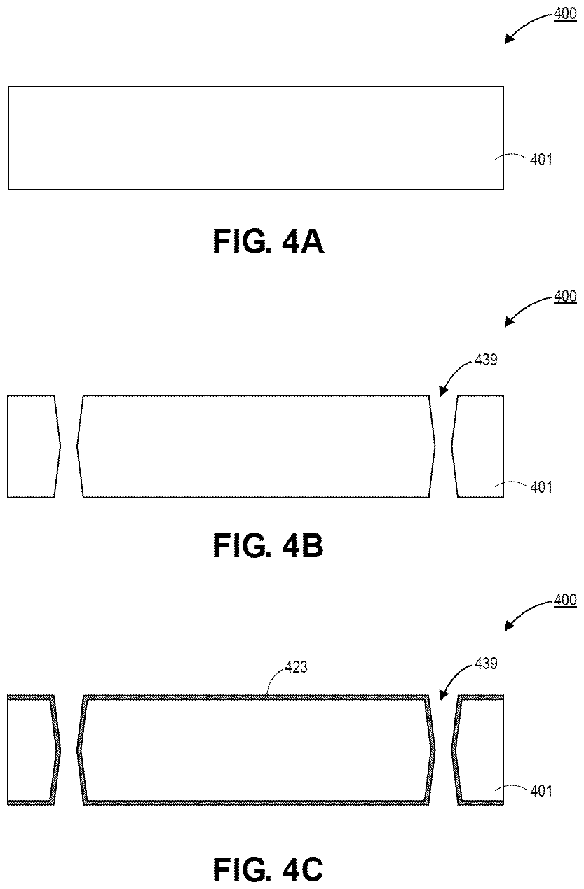

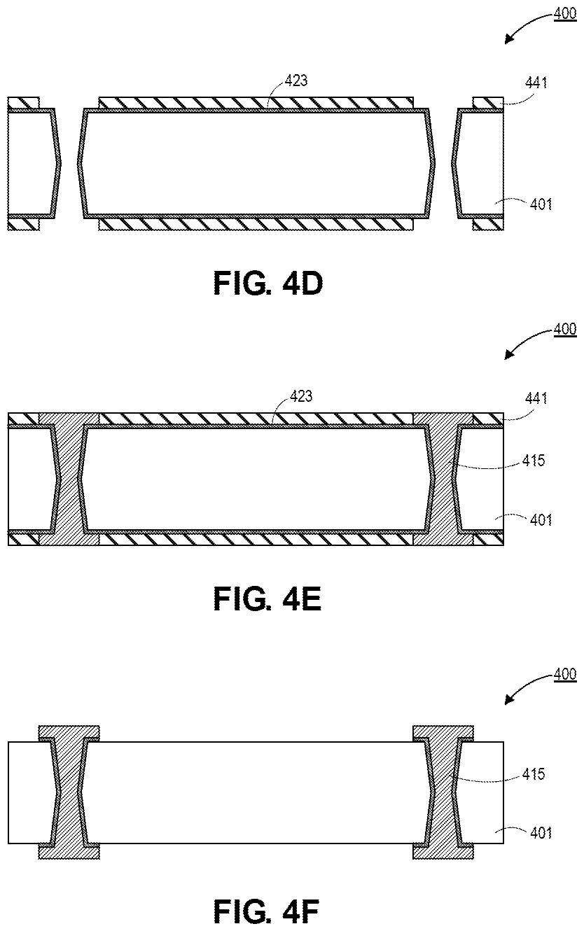

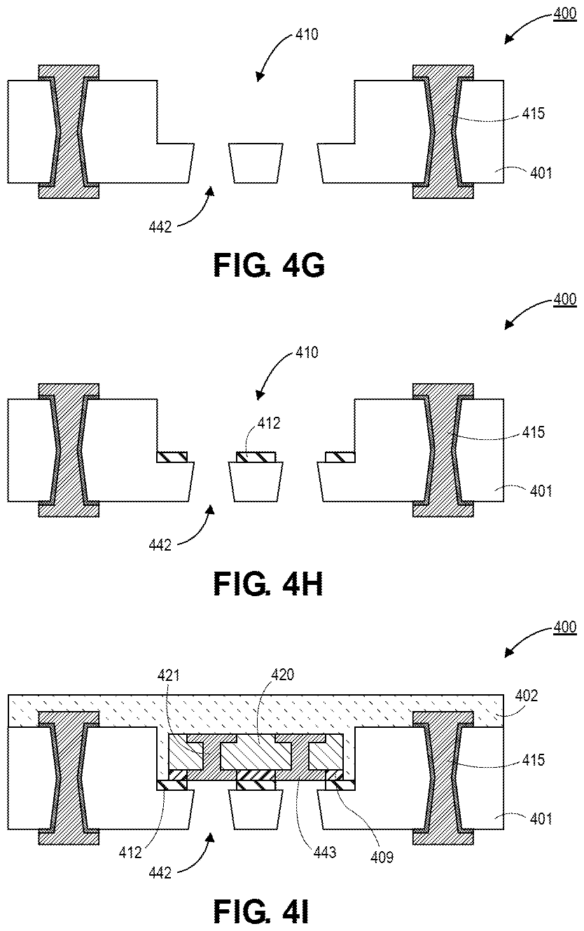

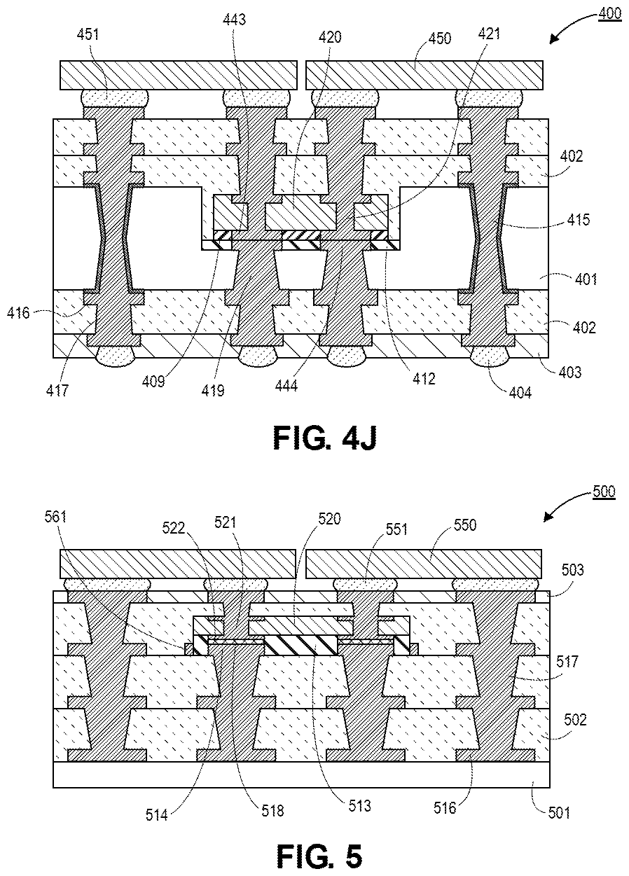

Referring now to FIGS. 4A-4J, a series of cross-sectional illustrations depicting a process for forming an electronic package 400 is shown, in accordance with an embodiment. In an embodiment, the electronic package 400 may be similar to the electronic package 300 described with respect to FIG. 3.

Referring now to FIG. 4A, a cross-sectional illustration of the electronic package 400 at a stage of manufacture is shown, in accordance with an embodiment. In FIG. 4A, a core 401 is illustrated. The core 401 may comprise glass. The glass formulation of the core 401 may be a glass that is compatible with laser assisted patterning processes. In an embodiment, the core 401 may have any suitable thickness. For example, the thickness of the core 401 may be between approximately 50 μm and approximately 1,000 μm. Though, thicker or thinner cores 401 may be used in some embodiments.

Referring now to FIG. 4B, a cross-sectional illustration of the electronic package 400 after via openings 439 are formed is shown, in accordance with an embodiment. The via openings 439 may be formed with a laser assisted patterning process. In some embodiments a dual sided laser exposure is used. As such, the via openings 439 may have hourglass shaped cross-sections, though a single sided process may be used in other embodiments. In such instances, the via openings 439 may have a single taper (e.g., wider at the top and narrower at the bottom).

Referring now to FIG. 4C, a cross-sectional illustration of the electronic package 400 after a seed layer 423 is applied is shown, in accordance with an embodiment. In an embodiment, the seed layer 423 may comprise titanium and copper. The seed layer 423 may be a conformal layer that lines the via openings 439. In an embodiment, the seed layer 423 may be applied with a sputtering process or the like.

Referring now to FIG. 4D, a cross-sectional illustration of the electronic package 400 after a resist layer 441 is applied over the top and bottom of the core 401 is shown, in accordance with an embodiment. In an embodiment, the resist layer 441 may be patterned to form openings that are aligned with the via openings 439.

Referring now to FIG. 4E, a cross-sectional illustration of the electronic package 400 after TGVs 415 are formed through the core 401 is shown, in accordance with an embodiment. The TGVs 415 may be formed with a plating process, such as an electrolytic plating process. In an embodiment, pads may be provided over and under the TGVs 415.

Referring now to FIG. 4F, a cross-sectional illustration of the electronic package 400 after the resist layer 441 and the seed layer 423 are removed is shown, in accordance with an embodiment. In an embodiment, the resist layer 441 may be removed with a resist stripping process or the like. The exposed portions of the seed layer 423 may be removed with a flash etching process. Removal of the seed layer 423 exposes portions of the top and bottom surface of the core 401.

Referring now to FIG. 4G, a cross-sectional illustration of the electronic package 400 after a cavity 410 and backside via openings 442 are formed is shown, in accordance with an embodiment. In an embodiment, the cavity 410 and the backside via openings 442 may be formed with a laser assisted patterning process. While the sidewalls of the cavity 410 are shown as being substantially vertical, it is to be appreciated that tapered sidewalls may be included in some embodiments. The backside via openings 442 start at the backside of the core 401 and extend up to a bottom surface of the cavity 410.

Referring now to FIG. 4H, a cross-sectional illustration of the electronic package after a PID 412 is applied along a bottom of the cavity 410 is shown, in accordance with an embodiment. In an embodiment, the PID 412 may be applied with a spray coating process, or the like. After the PID 412 is deposited, the PID 412 may be exposed and developed to form openings that are aligned over the backside via openings 442.

Referring now to FIG. 4I, a cross-sectional illustration of the electronic package after a bridge 420 is inserted into the cavity 410 is shown, in accordance with an embodiment. The bridge 420 may be a silicon substrate or the like. TSVs 421 may pass through a thickness of the bridge 420. Pads 443 may be provided at the bottom of the bridge 420. The pads 443 may be aligned with the openings 442. In an embodiment, the bridge 420 may be secured to the PID 412 by a DAF 409. After the bridge 420 is secured, a buildup layer 402 may be formed over the top surface of the core 401. The buildup layer 402 may fill the remainder of the cavity 410.

Referring now to FIG. 4J, a cross-sectional illustration of the electronic package 400 after further processing is shown, in accordance with an embodiment. As shown, vias 419 may be provided into the openings 442 in order to provide contact to the pads 443. Buildup layers 402 above and below the core 401 may be provided with conductive routing (e.g., pads 416, vias 417, and traces (not shown)) using SAP processes or other standard processing operations. A solder resist 403 for confining interconnects 404 may be provided on the bottom of the electronic package 400, and dies 450 with interconnects 451 may be provided at the top of the electronic package 400. In an embodiment, power is supplied to the dies 450 through the TSVs 421 through the bridge 420. The bridge 420 may also communicatively couple the two overlying dies 450 together.

In the embodiments described above, the bridge structure is embedded directly within the glass core. However, in other embodiments, the bridge structure may be embedded within one or more of the buildup layers. Such embodiments may also include glass core structures. An example of such an embodiment is shown in FIG. 5.

Referring now to FIG. 5, a cross-sectional illustration of an electronic package 500 is shown, in accordance with an embodiment. In an embodiment, the electronic package 500 comprises a core 501, such as a glass core. In an embodiment, TGVs (not shown) may be provided through the core 501. For ease of illustration the top side buildup layers 502 are shown, and the backside buildup layers and structures are omitted. In an embodiment, the buildup layers 502 may comprise conductive routing, such as pads 516, vias 517, traces (not shown), and the like.

In an embodiment, a bridge 520 is embedded in at least one of the buildup layers 502. In the illustrated embodiment, the bridge 520 is entirely within a single buildup layer 502. However, it is to be appreciated that the bridge 520 may have a thickness that requires the bridge 520 to be embedded in two or more buildup layers 502. In an embodiment, the bridge 520 may comprise TSVs 521. The TSVs 521 may be coupled to bottom pads 522. The bottom pads 522 may be coupled to pads 514 through interconnects 518 (e.g., solder). An underfill 513 may surround the pads 514 and 522, and interconnects 518.

Additionally, in some embodiments, conductive portions 561 may be provided outside edges of the underfill 513. The conductive portions 561 may be electrically conductive material (e.g., copper) that is a residual feature from the processing used to form the electronic package 500, as will be described in greater detail below. While electrically conductive, the conductive portions 561 may not be electrically connected to any of the functioning circuitry of the electronic package 500.

In an embodiment, the bridge 520 may communicatively couple a pair of overlying dies 550 together. Interconnects 551 over a solder resist layer 503 may be electrically coupled to the TSVs 521 through pads and vias. Power may be supplied to the overlying dies 550 over a path through the bridge 520 along the TSVs 521. As such, power routing does not need to be provided around the bridge 520.

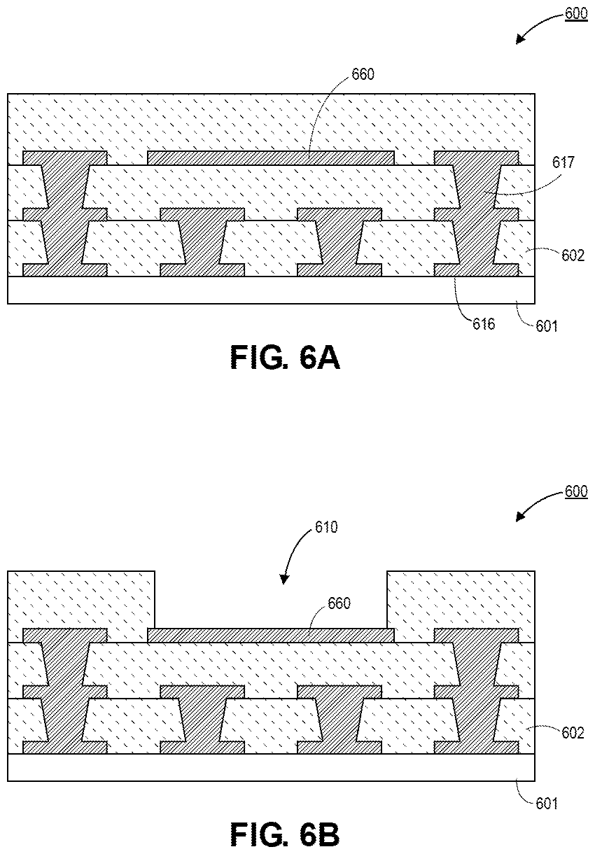

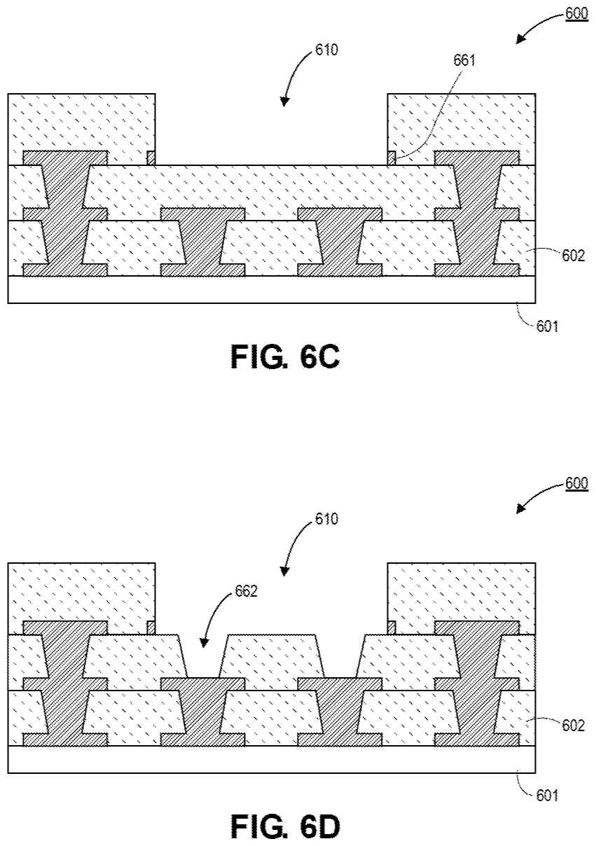

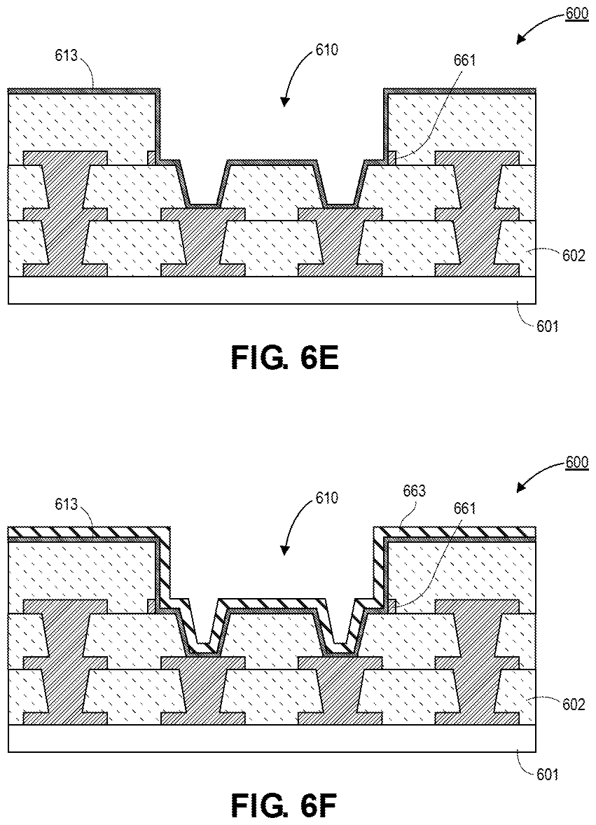

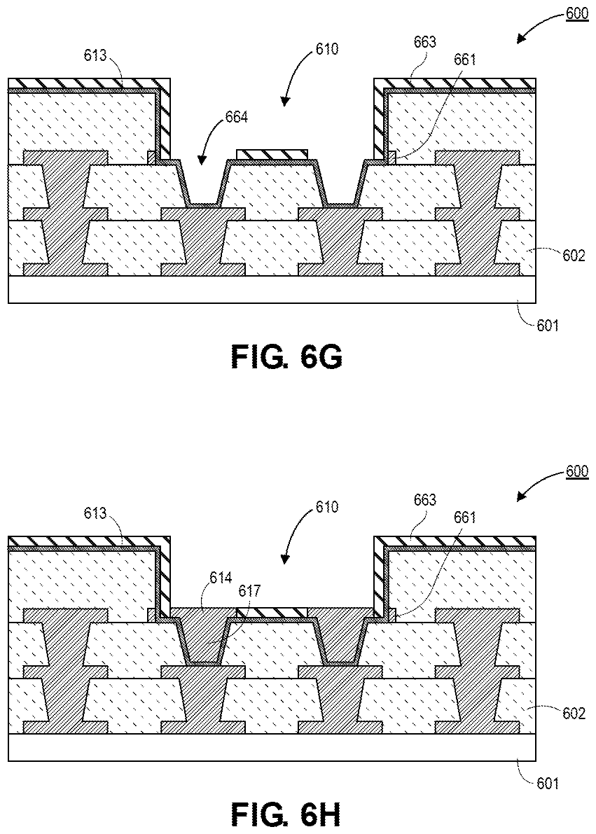

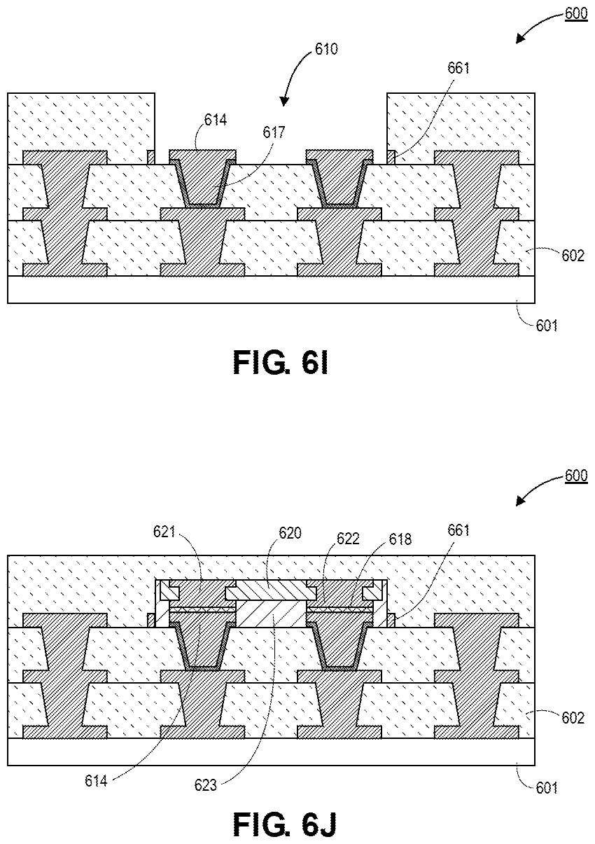

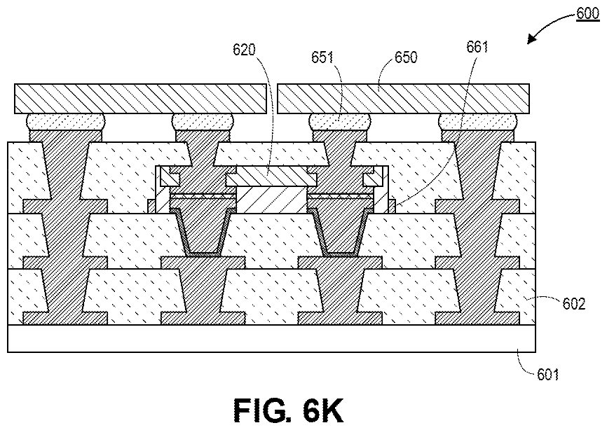

Referring now to FIGS. 6A-6K, a series of cross-sectional illustrations depicting a process for forming an electronic package 600 is shown, in accordance with an embodiment. In an embodiment, the electronic package 600 may be similar to the electronic package 500 described with respect to FIG. 5.

Referring now to FIG. 6A, a cross-sectional illustration of an electronic package 600 at a stage of manufacture is shown, in accordance with an embodiment. In an embodiment, the electronic package 600 comprises a core 601. The core 601 may be a glass core. In an embodiment, buildup layers 602 may be provided over and under the core 601. In FIG. 6A, only the structures above the core 601 are showed for simplicity. In an embodiment, conductive routing (e.g., pads 616, vias 617, and traces (not shown)) may be provided in the buildup layers 602. Additionally, a barrier layer 660 may be provided in the buildup layers 602. The barrier layer 660 may be used in order to form cavities of a desired depth in subsequent processing operations.

Referring now to FIG. 6B, a cross-sectional illustration of the electronic package 600 after a cavity 610 is formed is shown, in accordance with an embodiment. In an embodiment, the cavity 610 may be formed with a laser skiving process, or any other material removal process. The barrier layer 660 provides a stop point for the removal of the buildup layer 602. As such, the depth of the cavity 610 may be substantially uniform across a width of the cavity 610. In an embodiment, a width of the cavity 610 may be narrower than a width of the barrier layer 660.

Referring now to FIG. 6C, a cross-sectional illustration of the electronic package 600 after the barrier layer 660 is etched is shown, in accordance with an embodiment. The barrier layer 660 may be etched with a wet etching process or any other suitable etching process. As shown, conductive portions 661 may persist in the structure since the conductive portions 661 remain covered by the buildup layer 602. The conductive portions 661 may be electrically conductive (e.g., copper). However, the conductive portions 661 may be electrically isolated from functioning circuitry in the electronic package 600. In an embodiment, the inner edge of the conductive portions 661 may have a profile that is consistent with an isotropic etching process. For example, the inner edge may have some undercut or an otherwise non-vertical surface.

Referring now to FIG. 6D, a cross-sectional illustration of the electronic package 600 after via openings 662 are formed is shown, in accordance with an embodiment. In an embodiment, the via openings 662 may be provided at the bottom of the cavity 610. The via openings 662 may be formed with a laser ablation process or any other suitable material removal process.

Referring now to FIG. 6E, a cross-sectional illustration of the electronic package 600 after a seed layer 613 is applied is shown, in accordance with an embodiment. In an embodiment, the seed layer 613 may be applied with a sputtering process or the like. The seed layer 613 may comprise titanium and copper in some embodiments.

Referring now to FIG. 6F, a cross-sectional illustration of the electronic package 600 after a resist layer 663 is applied is shown, in accordance with an embodiment. In order to accommodate the topography of the cavity 610, the resist layer 663 may be applied with a spray coating process. This allows for both the sidewalls of the cavity 610 and the bottom of the cavity 610 to be covered by the resist layer 663.

Referring now to FIG. 6G, a cross-sectional illustration of the electronic package 600 after the resist layer 663 is patterned is shown, in accordance with an embodiment. The resist layer 663 may be patterned with a lithography operation in order to form openings 664. The openings 664 may be aligned over the via openings 662 at the bottom of the cavity 610.

Referring now to FIG. 6H, a cross-sectional illustration of the electronic package 600 after vias 617 and pads 614 are plated at a bottom of the cavity 610 is shown, in accordance with an embodiment. The plating process may be an electrolytic plating process or the like.

Referring now to FIG. 6I, a cross-sectional illustration of the electronic package 600 after the resist layer 663 is removed is shown, in accordance with an embodiment. In an embodiment, the resist layer 663 may be removed with a resist stripping process or the like. After the resist layer 663 is removed, the exposed portions of the seed layer 613 are removed (e.g., with a flash etching process).

Referring now to FIG. 6J, a cross-sectional illustration of the electronic package 600 after a bridge is inserted into the cavity 610 is shown, in accordance with an embodiment. In an embodiment, the bridge 620 may comprise TSVs 621 with pads 622 on a bottom of the bridge 620. The pads 622 may be electrically coupled to the pads 614 at the bottom of the cavity 610 through interconnects 618 (e.g., solder). In an embodiment, an underfill 623 may surround the pads 622, 614, and the interconnects 618. After the bridge 620 in inserted, a buildup layer 602 may be laminated over the top surface to fill the remainder of the cavity 610.

Referring now to FIG. 6K, a cross-sectional illustration of the electronic package 600 after dies 650 are attached is shown, in accordance with an embodiment. In an embodiment, vias may be provided through the buildup layers 602 to couple the dies 650 to the bridge 620. Interconnects 651 (e.g., solder or the like) may couple the dies 650 to the vias in the buildup layers 602. In an embodiment, the bridge 620 may communicatively couple the pair of dies 650 together. Additionally, power may be supplied to the dies 650 through the thicknesses of the bridge 620 (i.e., through the TSVs 621). As such, power routing does not need to be routed around the outer perimeter of the bridge 620.

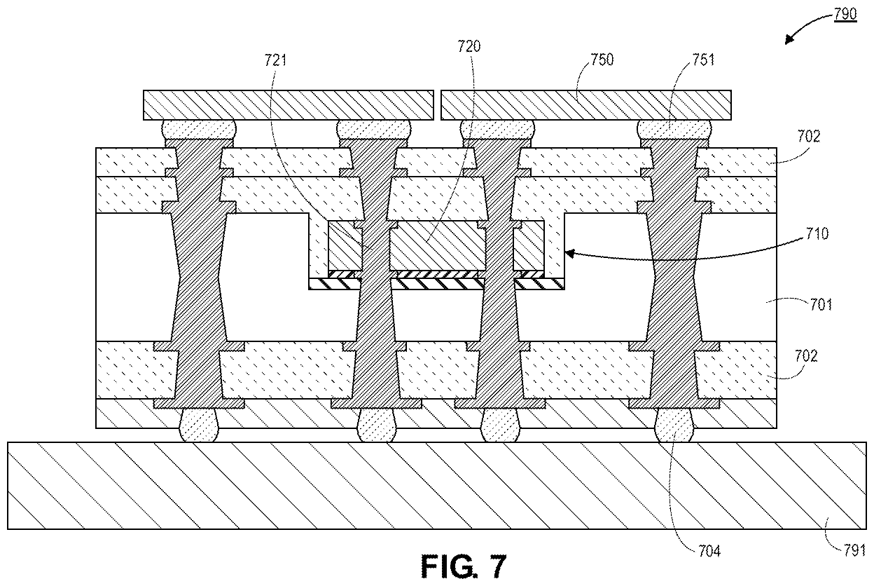

Referring now to FIG. 7, a cross-sectional illustration of an electronic system 790 is shown, in accordance with an embodiment. In an embodiment, the electronic system 790 comprises a board 791, such as a printed circuit board (PCB). The board 791 may be coupled to a buildup layer 702 by interconnects 704. The interconnects 704 may be solder balls or the like. In an embodiment, the buildup layer 702 may be provided over a core 701, such as a glass core 701. In an embodiment, additional buildup layers 702 may be over a top surface of the core 701.

In an embodiment, a bridge 720 may be inserted into a cavity 710 in the core 701. The bridge 720 may include TSVs 721. The TSVs 721 may route power through a thickness of the bridge 720. In an embodiment, the bridge 720 may also communicatively couple together a pair of dies 750. The dies 750 may be coupled to a buildup layer 702 through interconnects 751, such as solder or the like.

In the illustrated embodiment, the electronic package is similar to the electronic package 300 in FIG. 3. Though, it is to be appreciated that the electronic system 790 may include any of the electronic packages described in greater detail herein. For example, the electronic system 790 may comprise an electronic package similar to the electronic package 100 of FIG. 1, or an electronic package similar to the electronic package 500 in FIG. 5.

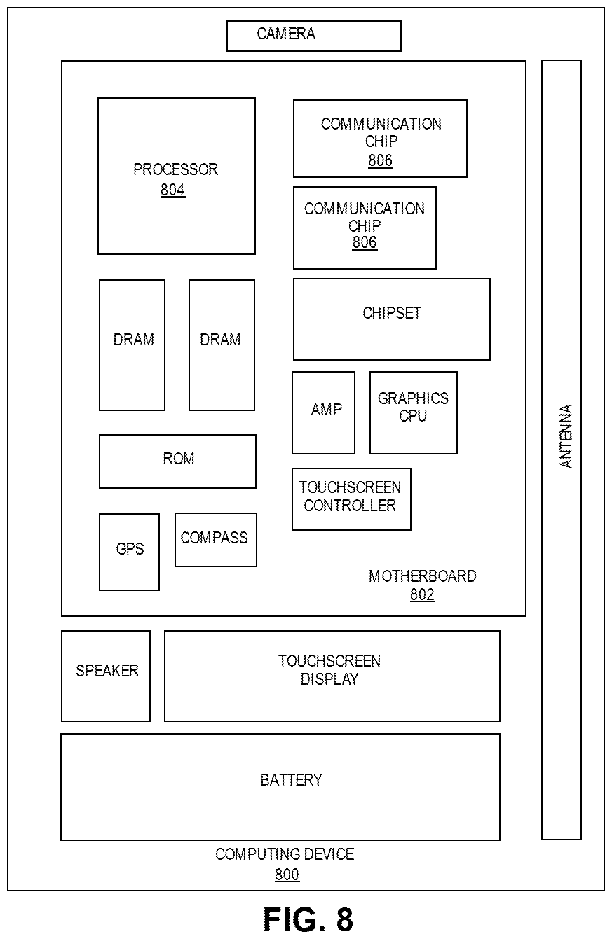

FIG. 8 illustrates a computing device 800 in accordance with one implementation of the invention. The computing device 800 houses a board 802. The board 802 may include a number of components, including but not limited to a processor 804 and at least one communication chip 806. The processor 804 is physically and electrically coupled to the board 802. In some implementations the at least one communication chip 806 is also physically and electrically coupled to the board 802. In further implementations, the communication chip 806 is part of the processor 804.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 806 enables wireless communications for the transfer of data to and from the computing device 800. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 806 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 800 may include a plurality of communication chips 806. For instance, a first communication chip 806 may be dedicated to shorter range wireless communications such as Wi-Fi and Bluetooth and a second communication chip 806 may be dedicated to longer range wireless communications such as GPS, EDGE, GPRS, CDMA, WiMAX, LTE, Ev-DO, and others.

The processor 804 of the computing device 800 includes an integrated circuit die packaged within the processor 804. In some implementations of the invention, the integrated circuit die of the processor may be part of an electronic package with a bridge with TSVs that is provided in a cavity in the package substrate, in accordance with embodiments described herein. The term “processor” may refer to any device or portion of a device that processes electronic data from registers and/or memory to transform that electronic data into other electronic data that may be stored in registers and/or memory.

The communication chip 806 also includes an integrated circuit die packaged within the communication chip 806. In accordance with another implementation of the invention, the integrated circuit die of the communication chip may be part of an electronic package with a bridge with TSVs that is provided in a cavity in the package substrate, in accordance with embodiments described herein.

In an embodiment, the computing device 800 may be part of any apparatus. For example, the computing device may be part of a personal computer, a server, a mobile device, a tablet, an automobile, or the like. That is, the computing device 800 is not limited to being used for any particular type of system, and the computing device 800 may be included in any apparatus that may benefit from computing functionality.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

Example 1: an electronic package, comprising: a core, wherein the core comprises glass; a cavity in the core; a bridge in the cavity, wherein the bridge comprises through substrate vias (TSVs); and pads at a bottom of the cavity, wherein the TSVs are electrically coupled to the pads.

Example 2: the electronic package of Example 1, wherein a liner lines sidewalls of the cavity and the bottom of the cavity.

Example 3: the electronic package of Example 2, wherein a photoimageable dielectric (PID) is provided over the liner at the bottom of the cavity.

Example 4: the electronic package of Example 2 or Example 3, wherein the liner comprises silicon and nitrogen.

Example 5: the electronic package of Examples 1-4, further comprising: vias through the core, wherein the vias are electrically coupled to the pads at the bottom of the cavity.

Example 6: the electronic package of Examples 1-5, further comprising: a photoimageable dielectric (PID) at the bottom of the cavity.

Example 7: the electronic package of Example 6, wherein a die attach film (DAF) is provided between the bridge and the PID, and wherein the DAF surrounds the pads.

Example 8: the electronic package of Examples 1-7, further comprising: a buildup layer over the core; and vias through the buildup layer that are coupled to the TSVs.

Example 9: the electronic package of Example 8, further comprising: a first die over the buildup layer; and a second die over the buildup layer, wherein the first die and the second die are coupled to the bridge through the vias.

Example 10: the electronic package of Examples 1-9, wherein a seed layer is provided between the pads and the bottom of the cavity.

Example 11: an electronic package, comprising: a core, wherein the core comprises glass; a buildup layer over the core; a bridge embedded in the buildup layer; and through substrate vias (TSVs) through the bridge.

Example 12: the electronic package of Example 11, further comprising: pads below the bridge, wherein the pads are electrically coupled to the TSVs.

Example 13: the electronic package of Example 12, wherein the TSVs are electrically coupled to the pads by solder.

Example 14 electronic package of Examples 11-13, further comprising: conductive portions outside a footprint of the bridge, wherein the conductive portions are not electrically coupled to circuitry of the electronic package.

Example 15: the electronic package of Examples 11-14, further comprising: a first die over the buildup layer; and a second die over the buildup layer, wherein the first die is communicatively coupled to the second die through the bridge.

Example 16: the electronic package of Example 15, wherein the first die and the second die are configured to receive power through the TSVs.

Example 17: an electronic system, comprising: a board; a package substrate coupled to the board, wherein the package substrate comprises: a core, wherein the core comprises glass; buildup layers over and under the core; and a bridge embedded in the package substrate, wherein the bridge comprises through substrate vias (TSVs); a first die coupled to the package substrate; and a second die coupled to the package substrate, wherein the first die is communicatively coupled to the second die by the bridge.

Example 18: the electronic system of Example 17, wherein the bridge is embedded in the core.

Example 19: the electronic system of Example 17, wherein the bridge is embedded in the buildup layers.

Example 20: the electronic system of Examples 17-19, wherein the electronic system is part of a personal computer, a server, a mobile device, a tablet, or an automobile.

What is claimed is:

1. An electronic package, comprising:
a core, wherein the core comprises glass;
a cavity in the core;
a bridge in the cavity, wherein the bridge comprises through substrate vias (TSVs); and
pads at a bottom of the cavity, wherein the TSVs are electrically coupled to the pads.

2. The electronic package of claim 1, wherein a liner lines sidewalls of the cavity and the bottom of the cavity.

3. The electronic package of claim 2, wherein a photoimageable dielectric (PID) is provided over the liner at the bottom of the cavity.

4. The electronic package of claim 2, wherein the liner comprises silicon and nitrogen.

5. The electronic package of claim 1, further comprising:
vias through the core, wherein the vias are electrically coupled to the pads at the bottom of the cavity.

6. The electronic package of claim 1, further comprising:
a photoimageable dielectric (PID) at the bottom of the cavity.

7. The electronic package of claim 6, wherein a die attach film (DAF) is provided between the bridge and the PID, and wherein the DAF surrounds the pads.

8. The electronic package of claim 1, further comprising:
a buildup layer over the core; and
vias through the buildup layer that are coupled to the TSVs.

9. The electronic package of claim 8, further comprising:
a first die over the buildup layer, and
a second die over the buildup layer, wherein the first die and the second die are coupled to the bridge through the vias.

10. The electronic package of claim 1, wherein a seed layer is provided between the pads and the bottom of the cavity.

11. An electronic package, comprising:
a core, wherein the core comprises glass;
a buildup layer over the core;
a bridge embedded in the buildup layer, and
through substrate vias (TSVs) through the bridge.

12. The electronic package of claim 11, further comprising:
pads below the bridge, wherein the pads are electrically coupled to the TSVs.

13. The electronic package of claim 12, wherein the TSVs are electrically coupled to the pads by solder.

14. The electronic package of claim 11, further comprising:
conductive portions outside a footprint of the bridge, wherein the conductive portions are not electrically coupled to circuitry of the electronic package.

15. The electronic package of claim 11, further comprising:
a first die over the buildup layer; and
a second die over the buildup layer, wherein the first die is communicatively coupled to the second die through the bridge.

16. The electronic package of claim 15, wherein the first die and the second die are configured to receive power through the TSVs.

17. An electronic system, comprising:
a board;
a package substrate coupled to the board, wherein the package substrate comprises:
a core, wherein the core comprises glass;
buildup layers over and under the core; and
a bridge embedded in the package substrate, wherein the bridge comprises through substrate vias (TSVs);
a first die coupled to the package substrate; and
a second die coupled to the package substrate, wherein the first die is communicatively coupled to the second die by the bridge.

18. The electronic system of claim 17, wherein the bridge is embedded in the core.

19. The electronic system of claim 17, wherein the bridge is embedded in the buildup layers.

20. The electronic system of claim 17, wherein the electronic system is part of a personal computer, a server, a mobile device, a tablet, or an automobile.
